(19) United States
(12) Patent Application Publication
(10) Pub. No.: US 2003/0002264 A1
(43) Pub. Date: Jan. 2, 2003

(54) Manufacturing method for a flexible PCB

(75) Inventors: Te-Sheng Yang, Taoyuan Hsien (TW); Chi-Rong Liu, Taoyuan Hsien (TW); Kuo-Chin Hsu, Taoyuan Hsien (TW)

Correspondence Address: Troxell Law Office PLLC, Suite 1404, 5205 Leesburg Pike, Falls Church, VA, 22041, US

(73) Assignee: UFLEX Technology Co., Ltd.

(21) Appl. No.: 10/159,027

(22) Filed: Jun. 3, 2002

(30) Foreign Application Priority Data
Jun. 29, 2001 (TW) 090115872

(51) Int. Cl. H05K 1/00

(52) U.S. Cl. 361/749

(57) ABSTRACT

A manufacturing method for a flexible PCB includes steps of forming a copper circuit on a first surface of a polyimide backing, removing unwanted polyimide by a laser processing to expose the copper circuit on a second surface of the backing, removing leavings of polyimide generated by the laser processing, and making a surface treatment to the copper circuit exposed at the second surface of the backing.

### BACKGROUND OF THE INVENTION

1. Field of the Invention

The present invention is related to a manufacturing method for a flexible PCB (Printed Circuit Board), and more particularly to a flexible PCB formed with single backing double exposed foil.

2. Description of Related Art

Referring to FIG. 3, a conventional manufacturing method for a flexible printed circuit board with single backing double exposed foil is illustrated. A polyimide backing (70) is first plated with a copper layer (71) at a first surface thereof, as shown in FIG. 3A. A first sensitive layer (72) is provided on the copper layer (71), as shown in FIG. 3B. A first circuit pattern is printed on the first sensitive layer (72) by shooting, exposing and developing, as shown in FIG. 3C. The unwanted sensitive material is removed and the first circuit pattern is then formed on the first sensitive layer (72), as shown in FIG. 3D. According to the circuit pattern on the first sensitive layer (72), the unwanted copper is removed by etching, as shown in FIG. 3E. Afterwards, the first sensitive layer (72) is removed and the copper circuit (710) is formed at the first surface of the backing (70), as shown in FIG. 3F.

A second sensitive layer (73) is provided on a second surface of the backing (70), as shown in FIG. 3G. A second circuit pattern is printed on the second sensitive layer (73) by shooting, exposing and developing, as shown in FIG. 3H. The unwanted sensitive material is removed and the second circuit pattern is then formed on the first sensitive layer (73), as shown in FIG. 3I. According to the second circuit pattern on the second sensitive layer (73), the unwanted polyimide is removed by etching, as shown in FIG. 3J. Finally, the second sensitive layer (73) is removed and the copper circuit (710) is exposed from the backing (70) to form the second circuit pattern, as shown in FIG. 3K.

In this process, there are two procedures of optical lithography to respectively form the circuit patterns on the both surfaces of the backing. The optical lithography need use poisonous chemical preparation in processing and will produce a lot of poisonous waste water, which is very harmful to environment.

Therefore, the invention provides an improved manufacturing method for a flexible PCB to mitigate and/or obviate the aforementioned problems.

### SUMMARY OF THE INVENTION

The main objective of the invention is to provide a manufacturing method for a flexible PCB which is advantageous to environment protection.

Another objective of the invention is to provide a manufacturing method for a flexible PCB which is simplified.

Other objects, advantages and novel features of the invention will become more apparent from the following detailed description when taken in conjunction with the accompanying drawings.

### BRIEF DESCRIPTION OF THE DRAWINGS

FIG. 1 is a diagram of a process for manufacturing a flexible PCB in accordance with the invention;

FIG. 2 is a schematic view showing the process for manufacturing the flexible PCB in accordance with the invention; and

FIG. 3 is a schematic view showing a conventional manufacturing method for the flexible PCB.

### DETAILED DESCRIPTION OF THE PREFERRED EMBODIMENT

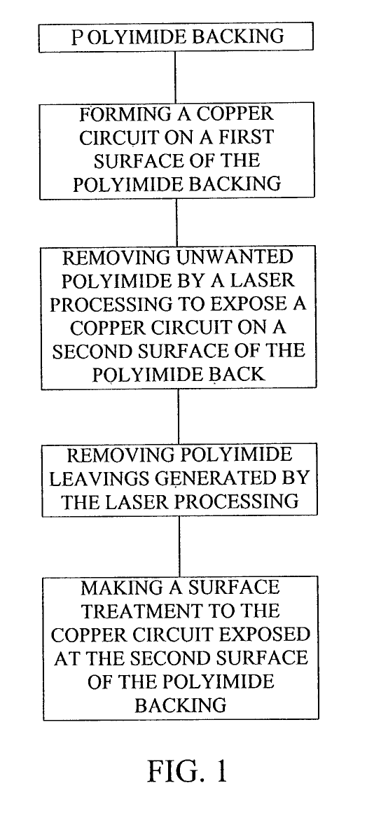

Referring to FIG. 1, a manufacturing method for a flexible PCB in accordance with the invention includes steps:

Forming a copper circuit on a first surface of a polyimide backing;

Removing unwanted polyimide by a laser processing to expose the copper circuit on a second surface of the backing;

Removing polyimide leavings generated by the laser processing; and

Making a surface treatment to the copper circuit exposed at the second surface of the backing.

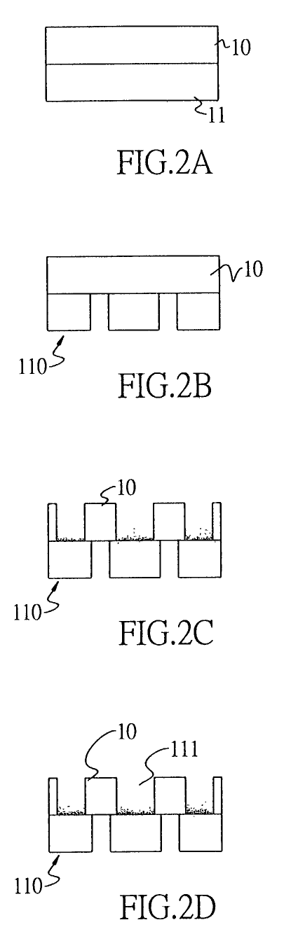

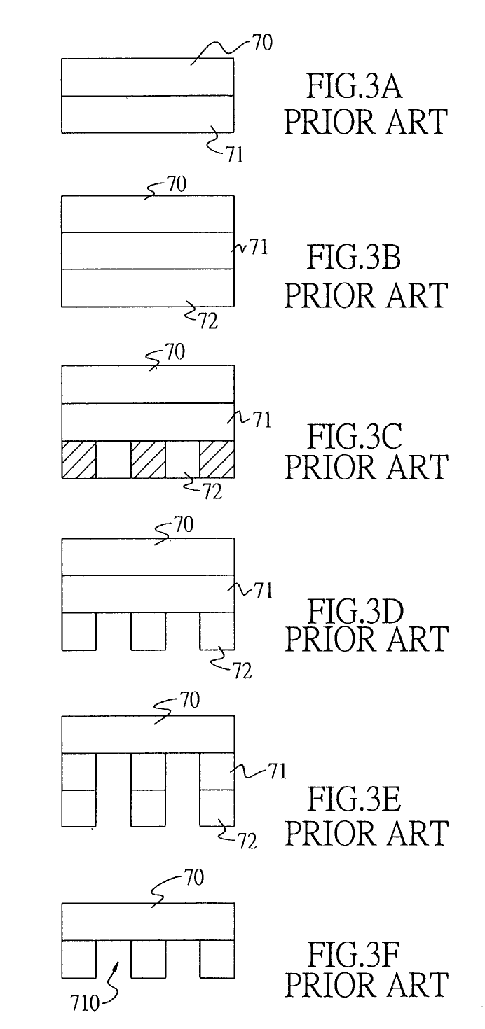

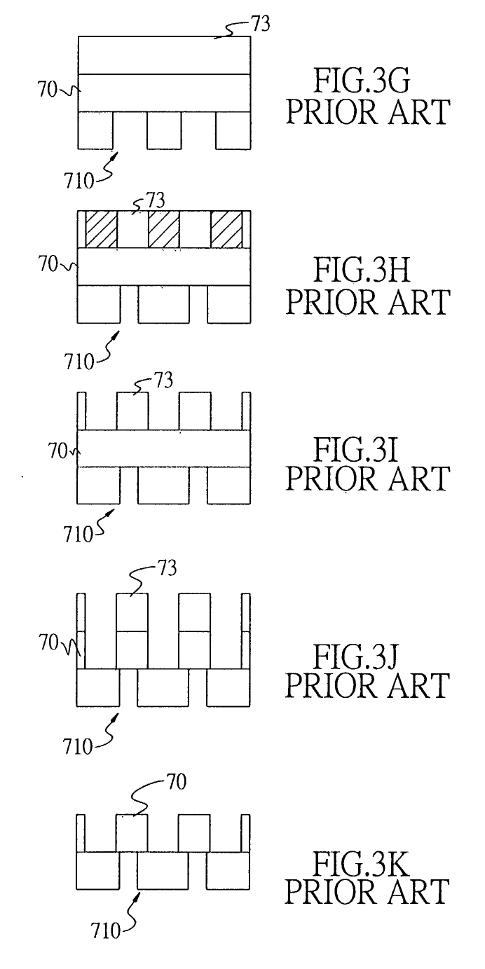

FIG. 2 shows a preferred embodiment according to the present invention. As shown in FIG. 2A, a copper layer (11) is formed on a polyimide backing (10). The backing (10) with the copper layer (11) has a double layers type and a triple layers type. In the former, the copper layer (11) is directly plated on a first surface of the backing (10), and in the latter, a layer of adhesive is provided between the copper layer and the backing (10). In this embodiment, the backing (10) with the copper layer (11) is the double layers type.

By a conventional procedure of optical lithography, a copper circuit (110) is formed on the first surface of the backing (10), as shown in FIG. 2B. The procedure of optical lithography includes following steps:

Covering the copper layer (11) with a sensitive layer (not shown or numbered);

Printing a first circuit pattern on the sensitive layer and removing unwanted sensitive material; and

Removing unwanted copper by etching according to the circuit pattern and removing the sensitive layer.

Thereafter, by a laser processing, the unwanted polyimide (10) is removed to define windows (111) on the backing (10) and the copper circuit (110) is exposed from these windows (111) to form a second circuit pattern on a second surface of the backing (10), as shown in FIG. 2C.

In the laser processing, the second circuit pattern is drawn in a computer by a CAD software such as AutoCAD and translated to machining information inputting a laser machine. According to these machining information, the laser machine can remove unwanted polyimide to define the windows (111) as the second circuit pattern. The laser source can be CO₂, YAG, or UV, etc.

Certainly, the copper circuit (110) on the first surface of the backing (10) also can be manufactured by the laser processing to remove unwanted copper.

When the laser source is CO₂, the backing (10) will have polyimide leavings (not numbered) in the windows (111) thereof, as shown in FIG. 2D. Thus, the backing (10) must be put in a cleaning solvent, of which a PH value is above 12, preferable 13 to 14, to remove these leavings. The cleaning solvent can be potassium permanganate, natrium permanganate, or alkaline solution. The preferable temperature of the cleaning solvent is above 75° C.

Afterwards, the PCB is put in a treating solvent to make a surface treatment for the copper circuit exposed on the second surface thereof. The treating solvent can be sulfuric acid, hydrogen peroxide, diluted sulfuric acid, or micro etchant.

From the above description, it is noted that the invention has the following advantages:

1. The manufacturing process is simple because the second surface of backing is machined by laser.

2. Because there is only one or no procedure of optical lithography in the manufacturing process, poisonous waste water is reduced greatly and it is very advantageous to environment protection.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A manufacturing method for a flexible PCB, comprising steps:
forming a copper circuit on a first surface of a polyimide backing;
removing unwanted polyimide by a laser processing to expose the copper circuit on a second surface of the backing; and
removing leavings of polyimide generated by the laser processing.

2. The manufacturing method for a flexible PCB as claimed in claim 1 further comprising a step of making a surface treatment to the copper circuit exposed at the second surface of the backing.

3. The manufacturing method for a flexible PCB as claimed in claim 1, wherein the copper circuit on the first surface of the backing is formed by a process of optical lithography including steps of:
covering the first surface of the backing with a copper layer;
covering the copper layer with a sensitive layer;
printing a first circuit pattern on the sensitive layer and removing unwanted sensitive material; and
removing unwanted copper by etching according to the circuit pattern on the sensitive layer and removing the sensitive layer.

4. The manufacturing method for a flexible PCB as claimed in claim 1, wherein the copper circuit on the first surface of the backing is formed by a laser processing.

5. The manufacturing method for a flexible PCB as claimed in claim 1, wherein the laser source in the laser processing is CO₂.

6. The manufacturing method for a flexible PCB as claimed in claim 1, wherein the laser source in the laser processing is YAG.

7. The manufacturing method for a flexible PCB as claimed in claim 1, wherein the laser source in the laser processing is UV.

8. The manufacturing method for a flexible PCB as claimed in claim 4, wherein the laser source in the laser processing is CO₂.

9. The manufacturing method for a flexible PCB as claimed in claim 4, wherein the laser source in the laser processing is YAG.

10. The manufacturing method for a flexible PCB as claimed in claim 4, wherein the laser source in the laser processing is UV.

11. The manufacturing method for a flexible PCB as claimed in claim 1, wherein the polyimide leavings is removed by a cleaning solvent of which a PH value is above 12.

12. The manufacturing method for a flexible PCB as claimed in claim 11, wherein the PH value of the cleaning solvent is 13 to 14.

13. The manufacturing method for a flexible PCB as claimed in claim 11, wherein the cleaning solvent is potassium permanganate.

14. The manufacturing method for a flexible PCB as claimed in claim 11, wherein the cleaning solvent is natrium permanganate.

15. The manufacturing method for a flexible PCB as claimed in claim 11, wherein the cleaning solvent is alkaline solution.

16. The manufacturing method for a flexible PCB as claimed in claim 2, wherein the surface treatment is made by a treating solvent.

17. The manufacturing method for a flexible PCB as claimed in claim 16, wherein the treating solvent issulfuric acid.

18. The manufacturing method for a flexible PCB as claimed in claim 16, wherein the treating solvent is diluted sulfuric acid.

19. The manufacturing method for a flexible PCB as claimed in claim 16, wherein the treating solvent is micro etchant.

20. The manufacturing method for a flexible PCB as claimed in claim 16, wherein the treating solvent is hydrogen peroxide.
